(19) United States
(12) Patent Application Publication
(10) Pub. No.: US 2013/0140712 A1
(43) Pub. Date: Jun. 6, 2013

(54) Array Substrate, LCD Device, and Method for Manufacturing Array Substrate

(71) Applicant: Hungjui Chen, Shenzhen (CN)

(72) Inventor: Hungjui Chen, Shenzhen (CN)

(73) Assignee: SHENZHEN CHINA STAR OPTOELECTRONICS TECHNOLOGY CO., LTD., Shenzhen, Guangdong (CN)

(21) Appl. No.: 13/380,875

(22) PCT Filed: Dec. 7, 2011
(86) PCT No.: PCT/CN2011/083655

§ 371 Date: Dec. 26, 2011

(30) Foreign Application Priority Data
Dec. 5, 2011 (CN) 2011103980440

(51) Int. Cl. H01L 33/36; H01L 21/768; H01L 23/50

(52) U.S. Cl. 257/775; 438/618; 257/E33.066; 257/E23.079; 257/E21.575

(57) ABSTRACT

The invention discloses an array substrate, an LCD device, and a method for manufacturing the array substrate. The array substrate comprises scan line(s) and data line(s); the width of data line at the junction of the data line and the scan line is more than the width of the rest part of the data line. The invention can improve the final passed yield of LCD devices on the premise of not adding additional processes, and has the advantages of simple technology and low cost.

### TECHNICAL FIELD

The invention relates to the field of liquid crystal displays (LCDs), and more particularly to an array substrate, an LCD device, and a method for manufacturing the array substrate.

### BACKGROUND

Conventional array substrates are manufactured by using the etching process: scan line(s) and data line(s) are sequentially etched on a transparent substrate in a layering mode. As shown in FIG. 1 and FIG. 2, an array substrate of an LCD device includes a plurality of thin film transistors (TFTs). Each TFT includes a substrate, a gate electrode, and a source electrode. The gate electrode is connected with the scan line, and the source electrode is connected with the data line. In the existing array substrate, the width of the data line after wet etching process becomes smaller and even disconnected, causing vertical disconnection or vertical line defects and thereby influencing the final passed yield.

### SUMMARY

The aim of the invention is to provide an array substrate, an LCD device, and a method for manufacturing the array substrate, in which the disconnection of data lines is not easy to occur.

The purpose of the invention is achieved by the following technical schemes.

An array substrate comprises scan line(s) and data line(s); the width of the data line at the junction of the data line and the scan line is more than the width of the rest part of the data line.

Preferably, the widened widths of the data line at both sides of the junction are equal. The strength applied onto both sides of the data line in the process of exposure and etching is quits; therefore, if widened widths are equal, the width of the data line after the process of exposure and etching is uniform, the phenomena of local narrowing and even disconnection will not occur.

Preferably, the widened width at one side of the data line at the junction is between 0.3 μm and 0.7 μm. Preferably, the width of the data line at the junction is not oversize; the larger the width is, the larger the overlapping area of the data line and the scan line is, and the easier the junction is broken-down when the array substrate produces static electricity; both sides are respectively widened for 0.5 μm, after the process of exposure, wet etching, etc., the width of the data line at the junction can be approximately accordant with the width of other parts, so that the overlapping area at the junction can be reduced on the premise of guaranteeing reliable connection.

Preferably, the widened width at one side of the data line at the junction is 0.5 μm. This is a preferable widened value.

An LCD device comprises the aforementioned array substrate.

A method for manufacturing the array substrate, comprises the step: setting the width parameter of a data line in the forming process of the data line of an array substrate so that the width of the data line at the junction of the data line and a scan line is more than the width of the rest part of the data line.

Preferably, the widened width of the data line at both sides of the junction is equal. The strength applied onto both sides of the data line after the process of exposure and etching is quits. Therefore, if widened widths are equal, the width of the data line after the process of exposure and etching is uniform, the phenomena of local narrowing and even disconnection will not occur.

Preferably, the widened width at one side of the data line at the junction is between 0.3 μm and 0.7 μm. Preferably, the width of the data line at the junction is not oversize; the larger the width is, the larger the overlapping area of the data line and the scan line is, and the easier the junction is broken-down when the array substrate produces static electricity; both sides are respectively widened for 0.5 μm, after the process of exposure, wet etching, etc., the width of the data line at the junction can be approximately accordant with the width of other parts, so that the overlapping area at the junction can be reduced on the premise of guaranteeing reliable connection.

Preferably, the widened width at one side of the data line at the junction is 0.5 μm. This is a preferable widened value.

In the invention, by research, the inventor finds that: when the data line is etched on the existing array substrate, the narrowing part or even disconnecting part of the data line occurs on the junction of the data line and the scan line; because the data line need to climb and cross over the scan line, the width (CD) of the data line in the climbing part is easily narrowed at the junction because of oversize amount of exposure in the climbing part in the process of exposure, and the width of the data line becomes smaller and even disconnected after the process of wet etching. In the invention, the data line is widened at the junction, and the appropriate width of the data line at the junction is still kept under the condition of width reduction after the data line at the junction is processed in the process of exposure, wet etching and the like, and then disconnection because of too narrow width does not occur. The invention solves the problems of width narrowing and even disconnection of the data line and can improve the final passed yield of LCD devices on the premise of not adding additional processes, and has the advantages of simple technology and low cost.

### BRIEF DESCRIPTION OF FIGURES

FIG. 1 is a schematic diagram of an array substrate of an LCD device of the prior art;

FIG. 2 is a schematic diagram of a data line at the junction in the process of exposure; and

FIG. 3 is a schematic diagram of an array substrate of an LCD device of the invention.

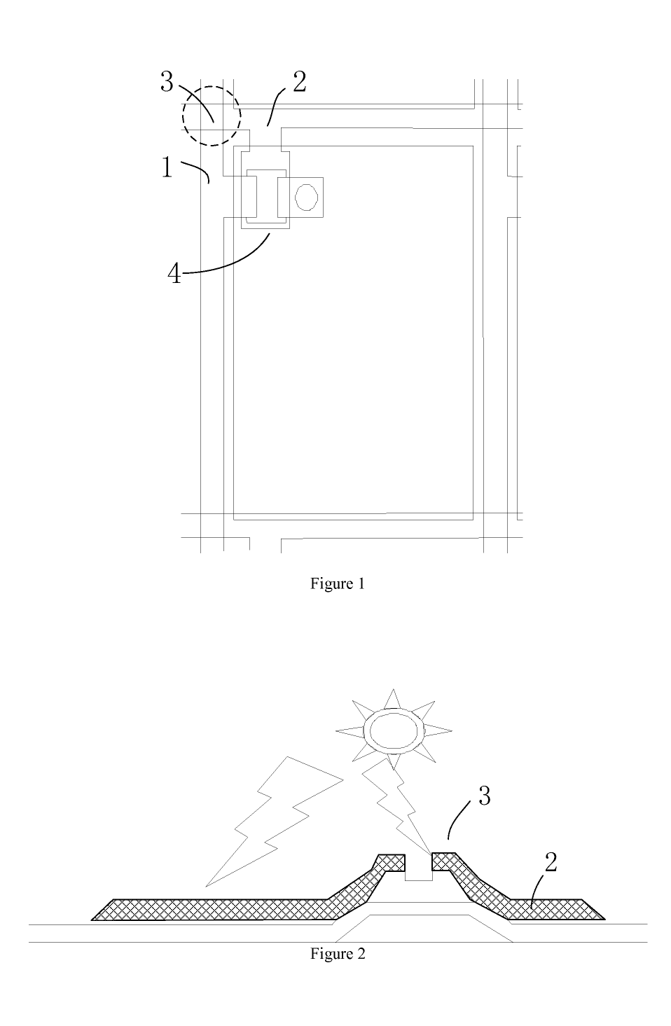

Wherein: 1. scan line; 2. data line; 3. junction; and 4. TFT.

### DETAILED DESCRIPTION

The invention will be further described in accordance with the figures and the preferred examples.

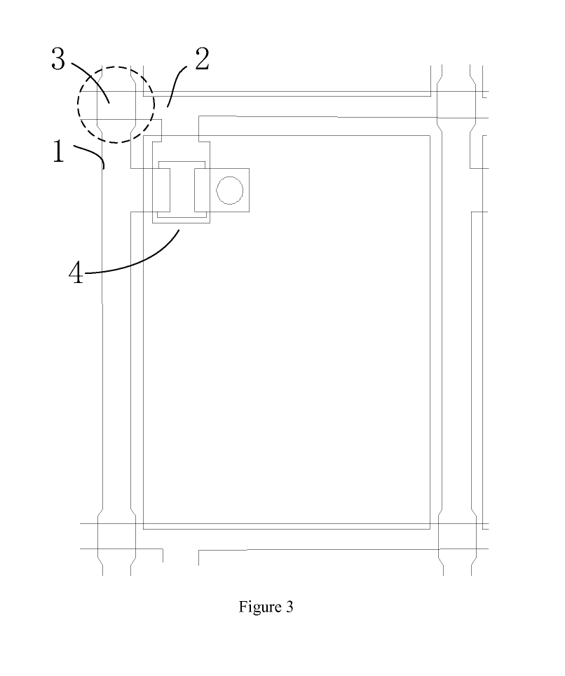

As shown in FIG. 3, an LCD device comprises an array substrate. The array substrate comprises a plurality of TFTs 4, scan line(s) 1 connected with the gate electrode of each TFT 4, and data lines(s) 2 connected with the source electrode of each TFT 4. The width of the data line 2 at the junction 3 of the data line 2 and the scan line 1 is more than the width of the rest part of the data line. Furthermore, the widened widths of the data line 2 at both sides of the junction 3 are equal. The strength applied onto both sides of the data line 2 in the process of exposure and etching are quits. Therefore, if widened widths are equal, the width of the data line 2 after the process of exposure and etching is uniform, and the phenomena of local narrowing and even disconnection will not occur.

Furthermore, the widened width at one side of the data line 2 at the junction 3 is between 0.3 μm and 0.7 μm. Preferably, the width of the data line 2 at the junction 3 is not oversize; the larger the width is, the larger the overlapping area of the data line 2 and the scan line 1 is, and the easier the junction 3 is broken-down when the array substrate produces static electricity; furthermore, both sides of the data line 2 at the junction 3 are respectively widened for 0.5 μm, after the process of exposure, wet etching, etc., the width of the data line 2 at the junction 3 can be approximately accordant with the width of other parts, so that the overlapping area 3 at the junction can be reduced on the premise of guaranteeing reliable connection.

The aforementioned method for manufacturing the array substrate, comprises the step:

Setting the width parameter of the data line 2 in the forming process of the data line 2 of the array substrate so that the width of the data line 2 at the junction 3 of the data line 2 and the scan line 1 is more than the width of the rest part of the data line 2.

Furthermore, the widened widths of the data line 2 at both sides of the junction 3 are equal when setting the width parameter of the data line 2. The strength applied onto both sides of the data line 2 in the process of exposure and etching is quits. Therefore, if widened widths are equal, the width of the data line 2 after the process of exposure and etching is uniform, and the phenomena of local narrowing and even disconnection will not occur. Correspondingly, the widened width at one side of the data line 2 at the junction 3 is between 0.3 μm and 0.7 μm. Preferably, the width of the data line 2 at the junction 3 is not oversize; the larger the width is, the larger the overlapping area of the data line 2 and the scan line 1 is, and the easier the junction 3 is broken-down when the array substrate produces static electricity; both sides are respectively widened for 0.5 μm, after the process of exposure, wet etching, etc., the width of the data line 2 at the junction 3 can be approximately accordant with the width of other parts, so that the overlapping area 3 at the junction can be reduced on the premise of guaranteeing reliable connection.

In the invention, by research, the inventor finds that: when the data line 2 is etched on the existing array substrate, the narrowing part or even disconnecting part of the data line 2 occur at the junction 3 of the data line 2 and the scan line 1; because the data line 2 need to climb and cross over the scan line 1, the width (CD) of the data line 2 in the climbing part is easily narrowed by the junction 3 because of oversize amount of exposure in the climbing part in the process of exposure, and the width of the data line becomes smaller and even disconnected after the process of wet etching. In the invention, the data line 2 at the junction 3 is widened, and the appropriate width of the data line 2 at the junction 3 is still kept under the condition of width reduction after the data line 2 at the junction 3 is processed in the process of exposure, wet etching, etc., and then disconnection because of too narrow width does not occur. The invention solves the problems of width narrowing and even disconnection of the data line 2 and can improve the final passed yield of LCD devices on the premise of not adding additional processes, and has the advantages of simple technology and low cost.

The invention is described in detail in accordance with the above contents with the specific preferred examples. However, this invention is not limited to the specific examples. For the ordinary technical personnel of the technical field of the invention, on the premise of keeping the conception of the invention, the technical personnel can also make simple deductions or replacements, and all of which should be considered to belong to the protection scope of the invention.

1. An array substrate comprises scan line(s) and data line(s); wherein the width of said data line at the junction of the data line and the scan line is more than the width of the rest part of the data line.

2. The array substrate of claim 1, wherein the widened widths of said data line at both sides of the junction are equal.

3. The array substrate of claim 1, wherein the widened width at one side of said data line at the junction is between 0.3 μm and 0.7 μm.

4. The array substrate of claim 3, wherein the widened width at one side of said data line at the junction is 0.5 μm.

5. An LCD device, comprising: the array substrate of claim 1; said array substrate comprises scan line(s) and data line(s); the width of said data line at the junction of the data line and the scan line is more than the width of the rest part of the data line.

6. The array substrate of claim 5, wherein the widened widths of said data line at both sides of the junction are equal.

7. The array substrate of claim 5, wherein the widened width at one side of said data line at the junction is between 0.3 μm and 0.7 μm.

8. The array substrate of claim 7, wherein the widened width at one side of said data line at the junction is 0.5 μm.

9. A method for manufacturing the array substrate, comprising the step: setting the width parameter of a data line in the forming process of the data line of an array substrate so that the width of the data line at the junction of the data line and a scan line is more than the width of the rest part of the data line.

10. The method for manufacturing the array substrate of claim 9, wherein the widened widths of said data line at both sides of the junction are equal.

11. The method for manufacturing the array substrate of claim 9. wherein the widened width at one side of said data line at the junction is between 0.3 μm and 0.7 μm.

12. The method for manufacturing the array substrate of claim 9, wherein the widened width at one side of said data line at the junction is 0.5 μm.

13. The array substrate of claim 2, wherein the widened width at one side of said data line at the junction is between 0.3 μm and 0.7 μm.

14. The array substrate of claim 13, wherein the widened width at one side of said data line at the junction is 0.5 μm.

15. The array substrate of claim 6, wherein the widened width at one side of said data line at the junction is between 0.3 μm and 0.7 μm.

16. The array substrate of claim 15, wherein the widened width at one side of said data line at the junction is 0.5 μm.

17. The method for manufacturing the array substrate of claim 10, wherein the widened width at one side of said data line at the junction is between 0.3 μm and 0.7 μm.

18. The method for manufacturing the array substrate of claim 17, wherein the widened width at one side of said data line at the junction is 0.5 μm.
